(19) United States
(12) Patent Application Publication
(10) Pub. No.: US 2017/0122980 A1
(43) Pub. Date: May 4, 2017

(54) CONTACT PROBE FOR A TESTING HEAD AND CORRESPONDING MANUFACTURING METHOD

(71) Applicant: Technoprobe S.p.A., Cernusco Lombardone (IT)

(72) Inventors: Roberto Crippa, Cernusco Lombardone (IT); Raffaele Ubaldo Vallauri, Cernusco Lombardone (IT); Emanuele Bertarelli, Cernusco Lombardone (IT)

(21) Appl. No.: 15/405,048

(22) Filed: Jan. 12, 2017

Related U.S. Application Data
(63) Continuation-in-part of application No. PCT/IB2015/054788, filed on Jun. 25, 2015.

(30) Foreign Application Priority Data
Jul. 14, 2014 (IT) MI2014A001279

(51) Int. Cl. G01R 1/067; H01R 43/16; B23K 26/40; H01R 43/02; B23K 1/19; B23K 1/00

(52) U.S. Cl. CPC G01R 1/06761; B23K 1/19; B23K 1/0016; B23K 26/40; H01R 43/02; H01R 43/16; B23K 2203/18

(57) ABSTRACT

A contact probe for a testing head of an apparatus for testing electronic devices is described comprising a body extending between a contact tip and a contact head, that contact probe comprising at least one first section and one second section made of at least two different materials and joined together in correspondence of a soldering line.

### BACKGROUND

Technical Field

The present disclosure refers to a contact probe for a testing head.

Particularly but not exclusively, the disclosure concerns a contact probe inserted in a testing head of an apparatus for testing electronic devices that are integrated on a wafer and the following description is carried out referring to this application field with the only purpose to simplify the exposition.

Description of the Related Art

As it is well known, a testing head or probe head is a device suitable to electrically connect a plurality of contact pads of a microstructure, particularly an electronic device that is integrated on a wafer, to corresponding channels of a testing machine performing the functional test thereof, particularly the electrical one, or generically the test.

The test being performed on integrated devices it is particularly useful to detect and isolate defective devices yet in the manufacturing step. Therefore, the testing heads are usually used to electrically test the devices that are integrated on a wafer before sawing and assembly them inside a chip package.

A testing head usually includes a high number of contact elements or contact probes made of special alloy wires having good mechanical and electrical properties and being provided with at least one contact portion for a corresponding plurality of contact pads of a device under test.

A testing head of the so-called vertical probe head type includes a plurality of contact probes held by at least one pair of plates or guides being substantially plate-shaped and parallel to each other. Those guides are provided with specific holes and are arranged at a certain distance from each other in order to leave a free space or air gap for the movement and possible deformation of the contact probes. The pair of guides particularly include an upper guide and a lower guide, both provided with respective guiding holes wherethrough the contact probes axially slide, the probes being usually made of special alloy wires having good electrical and mechanical properties.

The good connection between contact probes and contact pads of the device under test is ensured by pressing the testing head on the device itself. The contact probes, being movable inside the guiding holes made in the upper and lower guides during that pressing contact, undergo a bending inside the air gap between the two guides and a sliding inside those guiding holes.

Moreover, the contact probes bending in the air gap can be assisted by means of a proper configuration of the probes themselves or their guides, as schematically shown in FIG. 1, where, for sake of illustration simplicity, only one contact probe of the plurality of probes usually included in a testing head has been depicted, the shown testing head being of the so-called shifted plates type.

Particularly, in FIG. 1 a testing head 1 is schematically shown comprising at least one upper plate or guide 2 and one lower plate or guide 3, having respective upper 2A and lower 3A guiding holes wherein the at least one contact probe 4 slides.

The contact probe 4 has at least one contact end or tip 4A. The terms end or tip here and in the following specify an end portion, not necessarily being sharp. Particularly the contact tip 4A abuts on a contact pad 5A of a device under test 5, carrying out the electrical and mechanical contact between said device and a testing apparatus (not shown), that testing head forming a terminal element thereof.

In some cases, the contact probes are fixedly connected to the head itself at the upper guide: in such a case, the testing heads are referred to as blocked probes testing heads.

Alternatively, testing heads are used having probes not fixedly connected, but being interfaced to a board by means of a micro contact holder: those testing heads are referred to as non-blocked probes testing heads. The micro contact holder usually is called “space transformer” because, besides contacting the probes, it also allows spatially redistributing the contact pads made on it with respect to the contact pads existing on the device under test, particularly relaxing the distance constraints between the center of the pads themselves.

In this case, as shown in FIG. 1, the contact probe 4 has another contact tip 4B, usually indicated as contact head, towards a plurality of contact pads 6A of that space transformer 6. The good electrical contact between probes and space transformer is ensured similarly to the contact with the device under test by pressing the contact heads 4B of the contact probes 4 against the contact pads 6A of the space transformer 6.

As already explained, the upper 2 and lower 3 guides are conveniently separated by an air gap 7 allowing the deformation of the contact probes 4 and ensuring that contact tip and head of the contact probes 4 are contacting the contact pads of the device under test 5 and space transformer 6, respectively. Clearly, the upper 2A and lower 3A guiding holes should be sized in order to allow the contact probe 4 sliding therein.

In fact, it should be remembered that the proper operation of a testing head is essentially bound to two parameters: the vertical movement, or overtravel, of the contact probes and the horizontal movement, or scrub, of the contact tips of those probes.

Therefore, these characteristics are to be evaluated and calibrated in the testing head manufacturing step, since the good electrical connection between probes and device under test should always be guaranteed.

It is also possible to realize a testing head having contact probes protruding from a support, usually made of ceramic, possibly being conveniently pre-deformed in order to guarantee a consistent bending of the same when contacting the pads of a device under test. Moreover, those probes further deform when contacting the pads of the device under test.

For example, in the case of a testing head 1′ made in the technology known as Cobra, as schematically shown in FIG. 2, the contact probes 4′ have a pre-deformed configuration with a shift between contact tip 4A and contact head 4B already defined in the resting condition of the testing head 1′. Particularly in that case, the contact probe 4′ includes a pre-deformed portion 4C, which assists the proper bending of the contact probe 4′, even without contacting the testing head 1′ with the device under test 5. That contact probe 4′ further deforms during its operation, namely when in pressing contact with the device under test 5.

It should be noted that for a proper testing head operation, the contact probes should have a suitable degree of axial movement freedom inside the guiding holes. In such a way, those contact probes can also be extracted and replaced in case a single probe is broken, without being forced to replace the entire testing head.

That axial movement freedom, particularly the probes sliding inside the guiding holes, contrasts the normal safety requirements of the testing heads during their operation.

Particularly, in case of testing heads made using the shifted plates technology, it is verified that the risk the contact probes 4 come out during the maintenance and cleaning operations of the testing head 1 is very high, which operations are usually carried out using air blows or ultrasounds and therefore create mechanical stresses on the contact probes 4 and facilitate them in coming out from the guiding holes.

It should be also underlined that there are configurations widely used wherein the end portions of the contact probes 4, at the contact tip and head 4A and 4B and particularly including the probes portions being suitable to slide in the guiding holes 2A and 3A, are tilted with respect to those holes axes (that usually are perpendicular to a plane defined by the device under test), in order to ensure the desired scrub of the contact tips on the contact pads.

Therefore, the tilting of the end portions of the contact probes with respect to the guiding holes axes creates one or more contact points between probes and holes, suitable to partially hold the probes inside the holes.

However, it happens that the probes, and particularly their end portions, are held too much strongly inside the guiding holes, affecting the sliding freedom of the probes themselves and affecting the proper operation of the testing head as a whole. In extreme conditions, the contact probes can “get stuck” inside the guiding holes completely stopping the testing head operation and leading to the need of its replacement.

In order to eliminate or at least reduce these problems of probes got stuck in the guiding holes, it is also known to coat their end portions, namely the ones in correspondence of the contact tip and head of each probe, using a conductive material having a high hardness, particularly greater than that of the conductive material making the reminder of the probe. In such a way, in fact, the friction between the coated end portions and the walls of the guiding holes wherein they slide is reduced and therefore the contact probe wear in correspondence of those end portions is reduced too.

Therefore, in general, using a coating conductive material having a high hardness allows improving the sliding of contact probes into the respective guiding holes.

Clearly, the coating conductive material is selected in order to have a good electrical conductivity and therefore not to worsen the values measured by the contact probe significantly.

For example, it is known from the European patent application No. EP 2 060 921 to realize contact probes whose end portions are at least partially coated with a high hardness conductive layer, in particular gold, rhodium, platinum or a palladium-cobalt alloy.

Moreover, it is known from the US patent application No. US 2013/0099813 to realize contact probes having a cylindrical main body that includes a pillar-shaped central portion, an outer housing, which completely covers the central portion, and an adhesion layer therebetween.

Furthermore, the US patent application No. US 2012/0286816 discloses a high current capacity contact probe made of a first material, its distal end being coated with a second material and its contact tip being coated with a third material that can be different from the first and second materials.

It is also known to make the contact probes by means of multilayer structures, being able to optimize the different characteristics needed for their good operation, particularly their mechanical strength and electrical conductivity, besides the possibility to resiliently deform, in order to guarantee the proper contact with the contact pads of the device under test and of the space transformer.

More particularly, those multilayer probes are usually made starting from multilayer metal sheets wherein the contact probes are conveniently cut out, particularly by means of laser-cutting.

Multilayer probes made according to the known art include a central or core layer coated with one or more layers suitable to improve the electrical and hardness performances of the probe as a whole.

For example, a multilayer probe can include a core, for example made of tungsten, coated with a first high conductivity layer, for example made of gold, and a second layer having a high hardness, for example made of rhodium, these first and second layers being arranged on opposite sides of the core.

### BRIEF SUMMARY

The contact probe is able to guarantee a good electrical and mechanical contact with the contact pads of a device under test optimizing the characteristics of thermal and electrical conductivity and mechanical strength, avoiding problems of probes being damaged or stuck in the respective guiding holes at the same time, in order to overcome the limitations and disadvantages still concerning the testing heads being made according to the known art.

More particularly, the contact probes are made by means of a junction of at least one first conductive material having a high electrical and thermal conductivity and a second conductive material having high hardness and corrosion resistance.

The contact probe for a testing head of an apparatus for testing electronic devices comprises a body extending between a contact tip and a contact head and at least one first section and a second section made of at least two different materials and joined together in correspondence of a soldering line.

According to one aspect of the disclosure, the first section may be made of a first conductive material and the second section may be made of a second conductive material, the second conductive material having hardness values greater than those of the first conductive material.

Furthermore, the second conductive material may have surface roughness values lower than those of the first conductive material.

The first conductive material may also have values of electrical resistivity lower than 10 μΩ/cm and of thermal conductivity λ, greater than 110 W/(m·K).

According to another aspect of the disclosure, the first conductive material may be a metal or a metal alloy selected from copper, silver, gold or their alloys, such as alloys of copper-niobium or copper-silver, preferably copper.

Furthermore, according to another aspect of the disclosure, the second conductive material may have hardness values greater than 250 Hv in Vickers Scale (equivalent to 2451.75 MPa), preferably greater than 400 Hv in Vickers Scale (equivalent to 3922.8 MPa).

Moreover, the second conductive material may have values of surface roughness Ra lower than 0.05 micron, being Ra the average of the absolute value deviations of the real surface profile with respect to an average line.

According to another aspect of the disclosure, the second conductive material may be a metal or a metal alloy selected from nickel or an alloy thereof, such as nickel-manganese, nickel-cobalt or tungsten or an alloy thereof, such as nickel-tungsten, or a multilayer containing tungsten, or palladium or an alloy thereof, such as nickel-palladium or palladium-tungsten, or rhodium or an alloy thereof, preferably tungsten.

Furthermore, the first section may include a pre-deformed section.

According to another aspect of the disclosure, the first section may include the contact head of the contact probe and the second section may include the contact tip of the contact probe.

Furthermore, according to another aspect of the disclosure, the contact probe may include a further section joined to the first section in correspondence of a further soldering line.

Particularly, the first section may be centrally arranged with respect to a longitudinal axis of the contact probe and the second section and further section are arranged on opposite sides with respect to the first section at the end portions of the contact probe.

More particularly, the second section may include the contact tip and the further section may include the contact head.

Moreover, the further section may be made of the second conductive material making the second section or of a further conductive material different from the second conductive material making the second section, that further conductive material having hardness values greater than those of the first conductive material.

According to another aspect of the disclosure, the further conductive material may have surface roughness values lower than those of the first conductive material.

Moreover, the further conductive material may have hardness values greater than 250 Hv in Vickers Scale (equivalent to 2451.75 MPa), preferably greater than 400 Hv in Vickers Scale (equivalent to 3922.8 MPa).

The further conductive material may also have values of surface roughness Ra lower than 0.05 micron, being Ra the average of the absolute value deviations of the real surface profile with respect to an average line.

According to another aspect of the disclosure, the further conductive material may be a metal or a metal alloy selected from nickel or an alloy thereof, such as nickel-manganese, nickel-cobalt or tungsten or an alloy thereof, as nickel-tungsten, or a multilayer containing tungsten, or palladium or an alloy thereof, which nickel-palladium or palladium-tungsten or rhodium or an alloy thereof, preferably tungsten.

Furthermore, the contact probe may further include an outer coating layer made of a third conductive material having hardness values greater than those of the first and second conductive materials.

Particularly, the outer coating layer may have hardness values greater than 500 Hv in Vickers Scale (equivalent to 4903.5 MPa).

According to another aspect of the disclosure, the outer coating layer may be a metal or a metal alloy, in particular rhodium, platinum, or a metal alloy thereof or palladium or an alloy thereof, such as a palladium-cobalt alloy, a palladium-nickel alloy or even a nickel-phosphorus alloy, preferably rhodium.

A testing head of an apparatus for testing electronic devices includes a plurality of contact probes made as specified above.

Particularly, the testing head may include a plate-shaped ceramic support whereto the plurality of contact probes is fixedly connected in correspondence of the respective contact heads.

Alternatively, the testing head may include at least one pair of guides provided with respective guiding holes wherein the contact probes slide.

Finally, a method for manufacturing a contact probe made as stated above comprises the following steps:
preparing a multi-material laminate being obtained by soldering a first sheet made of a first conductive material to a second sheet made of a second material in correspondence of a soldering string; and
realizing a contact probe of the multi-material laminate in order to define a first section of the contact probe in the first sheet and a second section in the second sheet, joined in correspondence of a soldering line which is a portion of the soldering string.

According to another aspect of the disclosure, the step of preparing the multi-material laminate may comprise soldering a further sheet made of a further material to the first sheet in correspondence of a further soldering string and wherein the step of realizing also includes a definition of a further section in the further sheet, the first section and the further section being joined in correspondence of a further soldering line which is a portion of the further soldering string.

The soldering step may be carried out by means of a process selected from traditional welding, cladding, brazing.

Furthermore, the manufacturing method may further include a lamination step following the soldering step.

According to another aspect of the disclosure, the step of realizing the contact probe in the multi-material laminate may comprise a masking process and a following chemical etching, with one or more masking and etching steps.

Alternatively, the step of realizing the contact probe in the multi-material laminate may comprise a laser-cutting step.

According to another aspect of the disclosure, the laser-cutting step may include a plurality of passages of a cutting laser beam at a contour of the contact probe.

Finally, the laser-cutting step may include a number of passages of the cutting laser beam calibrated in order to separate the material of greater hardness used in the multi-material laminate.

The characteristics and advantages of the contact probe and the testing head according to the disclosure will result from the following description of one of its embodiments given by way of indicative and non-limiting example with reference to the attached drawings.

### BRIEF DESCRIPTION OF THE SEVERAL VIEWS OF THE DRAWINGS

FIG. 1 schematically shows a contact probe for a vertical probe testing head made according the known art;

FIG. 2 schematically shows a contact probe for a testing head in Cobra technology made according the known art;

FIGS. 3A and 3B schematically show a testing head comprising a free body contact probe according to one embodiment of the disclosure;

FIG. 4 schematically shows a testing head comprising a contact probe in vertical technology according to a further embodiment of the disclosure;

FIG. 5 schematically shows the contact probe of FIG. 3A during its manufacturing process; and

FIG. 6 schematically shows the contact probe of FIG. 4 during its manufacturing process.

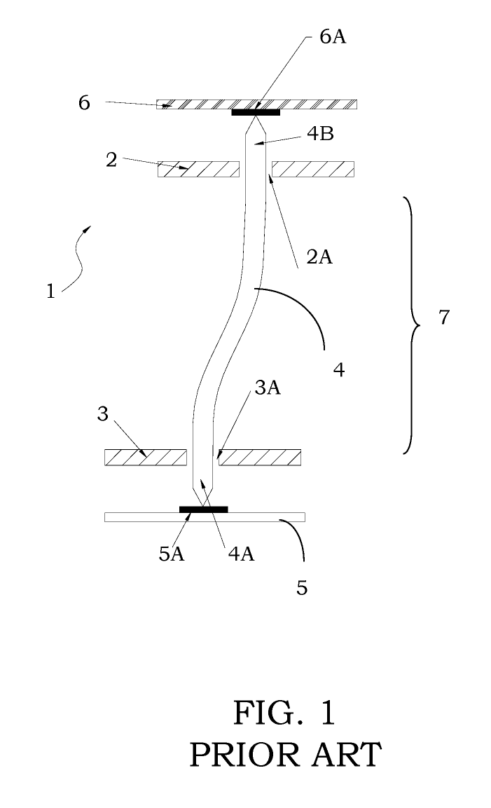

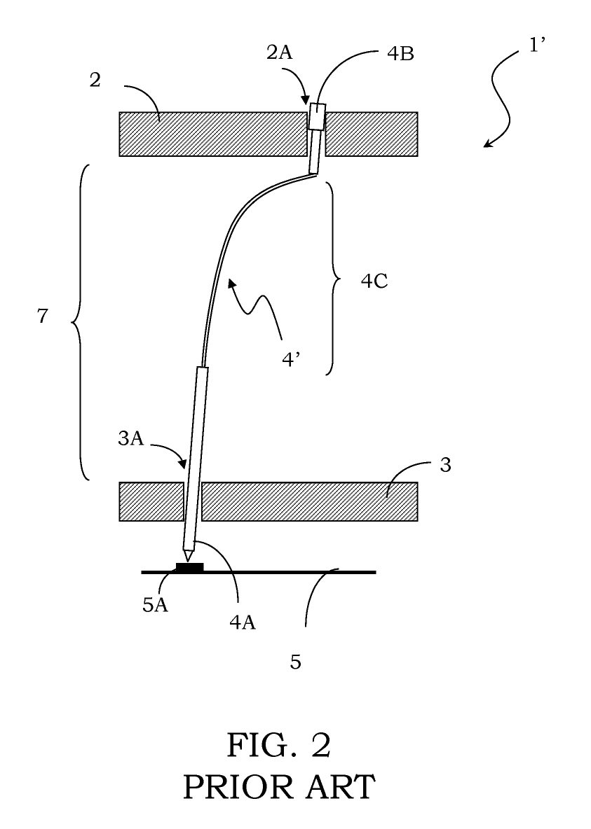

### DETAILED DESCRIPTION

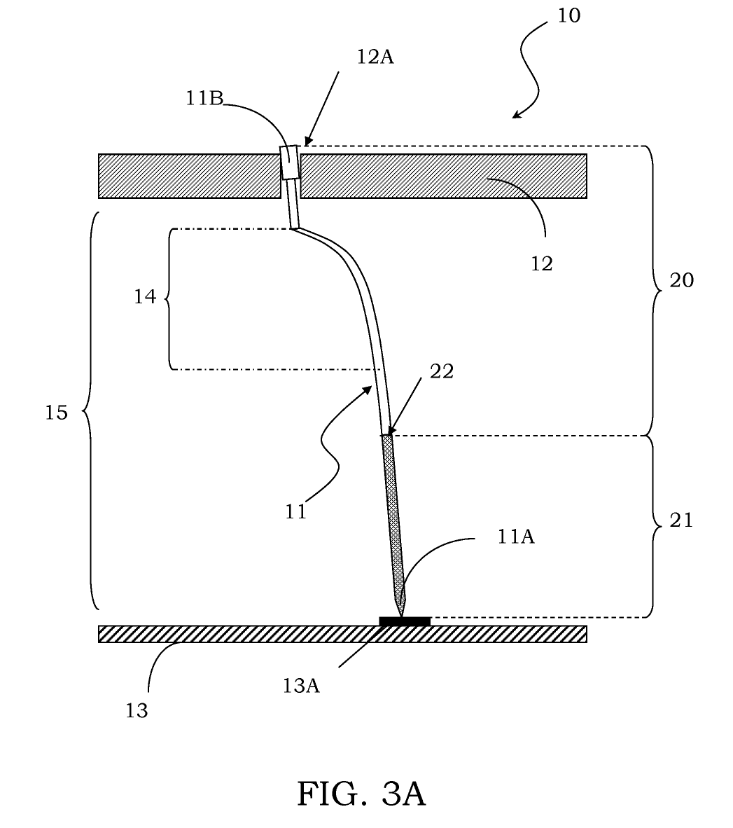

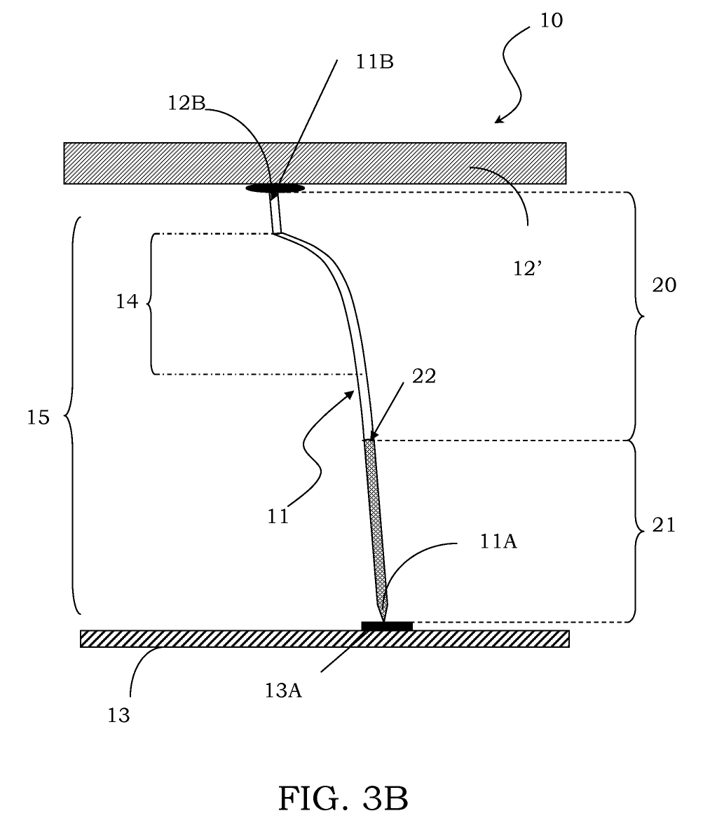

Referring to those figures and particularly to FIGS. 3A and 3B, now a contact probe for a testing head of an apparatus for testing electronic devices that are integrated on a wafer is described.

It should be noted that the figures show schematic views of the contact probe according to the embodiments of the disclosure and they are not drawn at scale, being drawn instead in order to underline the important features of the embodiments. In the figures, the different parts are shown schematically, their shape being able to vary according to the desired application. Moreover, the expedients being described related to one embodiment and shown in one figure can also be used in other embodiments shown in other figures.

The testing head 10 is shown, for sake of simplicity, as comprising only one contact probe 11, in turn comprising at least one contact tip 11A suitable to abut onto a contact pad 13A of a device under test 13.

The contact probe 11 may also include a head portion, also specified as contact head 11B, in that case being engaged in a guiding hole 12A of at least one upper plate or guide 12. That contact head 11B may abut on a contact pad of a space transformer, as in case of non-fastened vertical probes, or it may be fixedly associated, for example soldered, to a ceramic support, as in case of probes protruding from such a support.

Particularly, in the example shown in FIG. 3A, the contact probe 11 is a free body probe and its contact head 11B is housed in the guiding hole 12A of the upper guide 12. It is also possible to use a contact probe 11 of the free body type intended to be soldered to an external support 12′ acting as interface to a testing apparatus (not shown), as schematically shown in FIG. 3B. In that case, the contact probe 11, at the contact head 11B, has a soldering area 12B for that external support 12′.

The contact probe 11 also includes a pre-deformed section 14 arranged between the upper guide 12 or the external support 12′ and the device under test 13 in correspondence of an air gap 15 wherein, as explained relating to the known art, the pre-deformed section 14 further deforms when the contact tip 11A is in pressing contact on the contact pad 13A of the device under test 13.

According to an embodiment of the disclosure, the contact probe 11 includes at least one first section 20 and one second section 21 made of two different materials and joined together in correspondence of a soldering line 22 in order to form the contact probe 11. Particularly, the first section 20 includes the contact head 11B of the contact probe 11 while the second section 21 includes the contact tip 11A of the contact probe 11. Conveniently, the first section 20 includes the pre-deformed section 14 too.

It should be underlined that the term “soldering” is used to specify a solidarization between the first and the second section, solidarization that can be obtained by means of a traditional welding process, or alternatively by means of a cladding process or by brazing too.

The first section 20 is made of a first conductive material having high electrical and thermal conductivity values, particularly a metal or a metal alloy selected from copper, silver, gold or their alloys, such as alloys of copper-niobium or copper-silver, preferably copper. Particularly, that first conductive material has values of electrical resistivity lower than 10 μΩ/cm and of thermal conductivity λ, greater than 110 W/(m·K).

The second section 21 is instead made of a second conductive material, having hardness values greater than those of the first conductive material. Furthermore, the second conductive material has surface roughness values lower than those of the first conductive material again. Particularly, the second conductive material is a metal or a metal alloy selected from nickel or an alloy thereof, such as nickel-manganese, nickel-cobalt or tungsten or an alloy thereof, such as nickel-tungsten, or a multilayer containing tungsten, or palladium or an alloy thereof, such as nickel-palladium or palladium-tungsten, or rhodium or an alloy thereof, preferably tungsten. Particularly, the second conductive material has hardness values greater than 250 Hv in Vickers Scale (equivalent to 2451.75 MPa, using the conversion Hv×9,807=MPa), preferably greater than 400 Hv in Vickers Scale (equivalent to 3922.8 MPa).

Furthermore, the second conductive material has values of surface roughness Ra lower than 0.05 micron (being Ra the average of the absolute value deviations of the real surface profile with respect to an average line).

It should be underlined that the existence of the first section 20 having high conductivity, i.e. low resistivity, modifies the electrical behavior of the contact probe 11.

In fact, the existence of that high conductivity section, for example being made of copper, effectively realizes a resistor in series to the resistor of the second section 21 of the contact probe 11. In other words, it is as if the contact probe 11 was made of a material having a conductivity being the average of the conductivities of first conductive material of the first section 20 and second conductive material of the second section 21.

Therefore, in such a way, the contact probe 11 is able to withstand higher current densities compared to a traditional probe, for example completely made of tungsten, since most of the current applied to it is carried in its first section 20 having high conductivity or lower resistivity.

Finally, the existence of the first conductive material of the first section 20 having high conductivity guarantees a better heat dissipation by the contact probe 11.

The second conductive material of the second section 21 is instead selected in order to have higher hardness values compared to the first conductive material, thus improving the sliding of the contact tip 11A (made at that second section 21) on the contact pads 13A of the device under test 13. In such a way, the probe useful life is extended, its proper operation being guaranteed for a high number of testing operations wherein the contact tip 11A is in pressing contact on the contact pads 13A of a device under test 13 and also after several cleaning and re-shape operations on the tip itself usually involving abrasive clothes (the so-called cleaning “touch downs”).

It should also be underlined that the contact tip 11A of the contact probe 11, made in the second section 21 and thus of the second high hardness material, advantageously keeps its shape, also when used to contact pads made of very hard materials, such as copper pillars and micro copper pillars, and also after many cleaning “touch downs” of the tip itself on specific abrasive clothes.

According to one alternative embodiment, the contact probe 11 may also include an outer coating layer (not shown). Particularly, that outer coating layer may be made of a third conductive material having hardness values greater than those of the first and second conductive materials making the first section 20 and the second section 21, and particularly, hardness values greater than 500 Hv in Vickers Scale (equivalent to 4903.5 MPa). Preferably, the third conductive material is a metal or a metal alloy, in particular rhodium, platinum, or a metal alloy thereof or palladium or an alloy thereof, such as a palladium-cobalt alloy, a palladium-nickel alloy or even a nickel-phosphorus alloy. In one preferred embodiment of the disclosure, the outer coating layer is made of rhodium.

It should be underlined that the third conductive material is selected in order to have a good electrical conductivity, particularly electrical resistivity values lower than 10 μΩ/cm and therefore in order not to significantly worsen the values measured from the contact probe. Moreover, the outer coating layer allows giving the contact probe 11 an even greater outer hardness, particularly at its contact tip 11A.

Substantially, the outer coating layer generally improves the mechanical performance of the contact probe 11 as a whole.

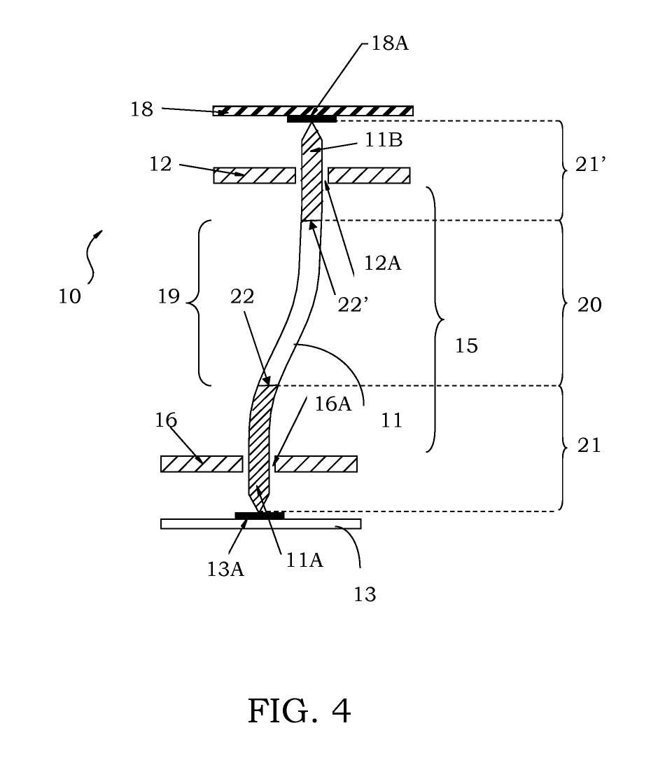

Alternatively, as shown in FIG. 4, a contact probe 11 according to an embodiment of the disclosure can be of the vertical type and be inserted in respective guiding holes of at least one pair of plates, being conveniently shifted.

In fact, in that case, as described relating to the known art, the testing head 10 includes, besides the upper plate or guide 12, also a lower plate or guide 16, having respective upper 12A and lower 16A guiding holes wherein the at least one contact probe 11 slides.

In that case also, the contact probe 11 has at least one contact end or tip 11A being suitable to abut on a contact pad 13A of the device under test 13.

In that case, the contact probe 11 has a further contact tip, usually indicated as contact head and always labelled as 11B in FIG. 4, towards a plurality of contact pads 18A of a space transformer 18. The good electrical contact between probes and space transformer is ensured in a way similar to the contact with the device under test by pressing the contact heads 11B of the contact probes 11 on the contact pads 18A of the space transformer 18. As already explained relating to the known art, the upper 12 and lower 16 guides are conveniently separated by an air gap 15 that allows the deforming of the contact probes 11 and ensures the contact tip and head of the contact probes 11 are contacting the contact pads of the device under test 13 and space transformer 18, respectively. Clearly, the upper 12A and lower 16A guiding holes should be sized in order to allow a sliding of the contact probe 11 therein.

Moreover, the contact probe 11 has a shifted section 19 that is obtained by a proper shifting of the upper 12 and lower 16 guides and that deforms during the testing head 10 operation, particularly when the contact tips 11A are in pressing contact on the contact pads 13A of the device under test 13 and the contact heads 11B are in pressing contact on the contact pads 18A of the space transformer 18.

According to one embodiment of the disclosure shown in FIG. 4, the contact probe 11 includes in that case the first section 20 and the second section 21 as well as a further section 21′.

Particularly, the first section 20 is arranged in correspondence of the center with respect to a longitudinal axis of the contact probe 11 and includes the shifted section 19 while the second section 21 and the further section 21′ are arranged on opposite sides with respect to the first central section 20, particularly in correspondence of the end portions of the contact probe 11; more particularly, the second section 21 includes the contact tip 11A of the contact probe 11 while the further section 21′ includes the contact head 11B of the contact probe 11.

Conveniently, those central section 20 and end sections 21 and 21′ are made of at least two different materials and are joined together in correspondence of soldering lines 22, 22′ to form the contact probe 11. Particularly, the first section 20 is joined to the second section 21 in correspondence of the soldering line 22 and to the further section 21′ in correspondence of the further soldering line 22′.

It should be underlined that, by virtue of the configuration in sections of the contact probe 11 according to an embodiment of the disclosure, only the end portions contact the guiding holes provided in the plate-shaped guides of the testing head that includes the contact probe 11.

Conveniently, according to this embodiment too, the first section 20 is made of a first conductive material having high electrical and thermal conductivity values, particularly a metal or a metal alloy selected from copper, silver, gold or their alloys, such as alloys of copper-niobium or copper-silver, preferably copper. Particularly, that first conductive material has values of electrical resistivity lower than 10 μΩ/cm and of thermal conductivity λ, greater than 110 W/(m·K).

The second section 21 and the further section 21′ are both made of a second conductive material, having hardness values greater than those of the first conductive material. Furthermore, the second conductive material has surface roughness values lower than those of the first conductive material again. Particularly, the second conductive material is a metal or a metal alloy selected from nickel or an alloy thereof, such as nickel-manganese, nickel-cobalt or tungsten or an alloy thereof, such as nickel-tungsten, or a multilayer containing tungsten, or palladium or an alloy thereof, such as nickel-palladium or palladium-tungsten, or rhodium or an alloy thereof, preferably tungsten. Particularly, the second conductive material has hardness values greater than 250 Hv in Vickers Scale (equivalent to 2451.75 MPa), preferably greater than 350 Hv in Vickers Scale (equivalent to 3432.45 MPa). Furthermore, the second conductive material has values of surface roughness Ra lower than 0.05 micron (being Ra the average of the absolute value deviations of the real surface profile with respect to an average line).

Alternatively, the further section 21′ may be made by a further conductive material different from the second conductive material making the second section 21. The further conductive material also is selected in order to have hardness values greater than those of the first conductive material. Furthermore, the further conductive material has surface roughness values lower than those of the first conductive material again. Similarly, the further conductive material is a metal or a metal alloy selected from nickel or an alloy thereof, such as nickel-manganese, nickel-cobalt or tungsten or an alloy thereof, such as nickel-tungsten, or a multilayer containing tungsten, or palladium or an alloy thereof, such as nickel-palladium or palladium-tungsten, or rhodium or an alloy thereof, preferably tungsten and has hardness values greater than 250 Hv in Vickers Scale (equivalent to 2451.75 MPa), preferably greater than 400 Hv in Vickers Scale (equivalent to 3922.8 MPa). Further, the further conductive material has values of surface roughness Ra lower than 0.05 micron (being Ra the average of the absolute value deviations of the real surface profile with respect to an average line).

In that way, when the contact probe 11 is slidingly assembled in the guiding holes being provided in plate-shaped guides, particularly ceramic ones, abrasions or “scratches” of the probe itself do not occur during the operation.

Moreover, as before, the contact tip 11A made of this further material, advantageously keeps its shape, also when used to contact pads made of very hard materials, such as copper pillars and micro copper pillars, and also after many cleaning “touch downs” of the tip itself on specific abrasive clothes.

A testing head will include a plurality of probes of the type of the contact probe 11 according to an embodiment of the disclosure. Particularly, such a testing head could include a plate-shaped support, particularly a ceramic one, to which the plurality of contact probes is fixedly connected at the probe heads, while the probe tips freely protrude starting from the plate-shaped support in order to abut onto a corresponding plurality of contact pads of a device under test, as shown in FIGS. 3A and 3B for just one contact probe 11.

Alternatively, the testing head could include an upper guide and a lower guide relatively spaced from each other in order to define an air gap and being provided with respective upper and lower guiding holes wherein the plurality of contact probes slide, as shown in FIG. 4 for just one contact probe 11.

The disclosure also refers to a method for manufacturing a contact probe 11 of the type described above.

The method for manufacturing a contact probe 11 of the type shown in FIG. 3, for example, includes particularly the following steps:
preparing a multi-material laminate 23 being obtained by soldering a first sheet 24 made of a first conductive material to a second sheet 25 made of a second material in correspondence of a soldering string 26; and
realizing a contact probe 11 of the multi-material laminate 23 in order to define a first section 20 of the contact probe 11 in the first sheet 24 and a second section 21 in the second sheet 25, joined in correspondence of a soldering line 22 which is a portion of the soldering string 26.

In that case also, the term “soldering” is used to specify a solidarization between the first and the second sheets to form the multi-material laminate 23, solidarization that can be obtained by means of a traditional welding process, or alternatively by means of a cladding process or by brazing too.

The manufacturing method may also include a further lamination step, particularly to planarize the multi-material laminate 23 after solidarization, for example removing any surface non-homogeneity of the multi-material laminate 23 itself left after soldering.

Furthermore, the step of realizing the contact probe 11 in the multi-material laminate 23 may be carried out by laser-cutting or by means of a masking process and a following chemical etching, which in turn can include one or more masking and etching steps.

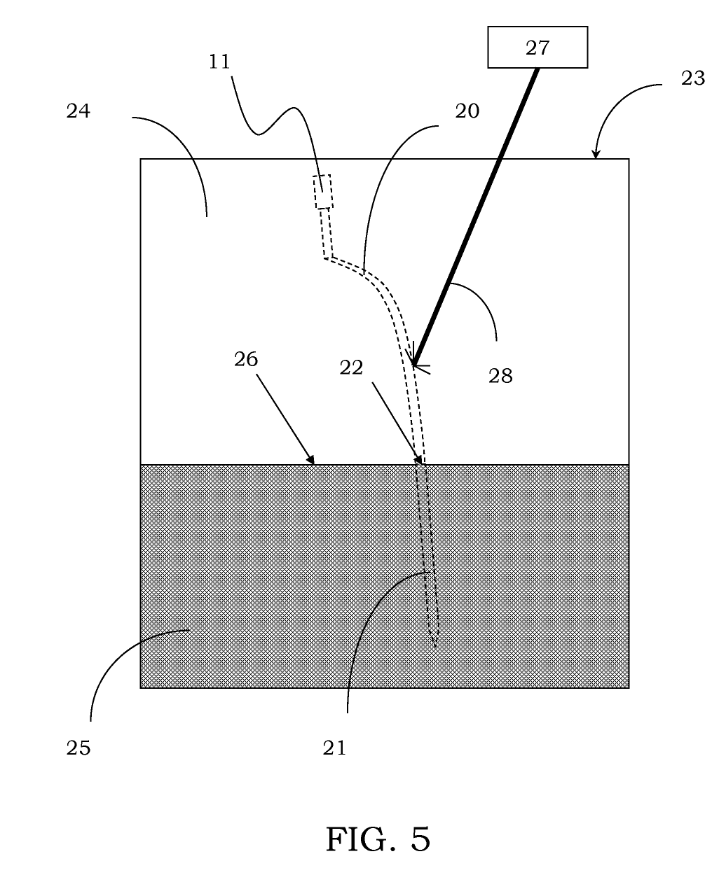

As shown in FIG. 5, the laser-cutting operation can be carried out for example by means of a dedicated laser equipment 27 able to direct a cutting laser beam 28 on the multi-material laminate 23.

In a very similar way, it is possible to manufacture a contact probe 11 of the type shown in FIG. 4 by means of a process comprising the following steps:
preparing a multi-material laminate 23 being obtained by soldering a first sheet 24 made of a first conductive material to a second sheet 25 made of a second material in correspondence of a soldering string 26 and a further sheet 25′ made of a further material at a further soldering string 26′; and
realizing a contact probe 11 in the multi-material laminate 23 in order to define a first section 20 of the contact probe 11 in that first sheet 24, a second section 21 in that second sheet 25 and a further section 21′ in that further sheet 25′, the first section 20 and the second section 21 being joined in correspondence of a soldering line 22 which is a portion of the soldering string 26 and the first section 20 and the further section 21′ being joined in correspondence of a further soldering line 22′ which is a portion of the further soldering string 26′.

In that case also, the term “soldering” is used to specify a solidarization between the first and the second sheets to form the multi-material laminate 23, solidarization that can be obtained by means of a traditional welding process, or alternatively by means of a cladding process or by brazing too.

The method may also include a further lamination step, particularly to planarize the multi-material laminate 23 after solidarization, for example removing any surface non-homogeneity of the multi-material laminate 23 itself left after soldering.

Furthermore, the step of realizing the contact probe 11 in the multi-material laminate 23 may be carried out by laser-cutting or by means of a masking process and a following chemical etching, which in turn can include one or more masking and etching steps.

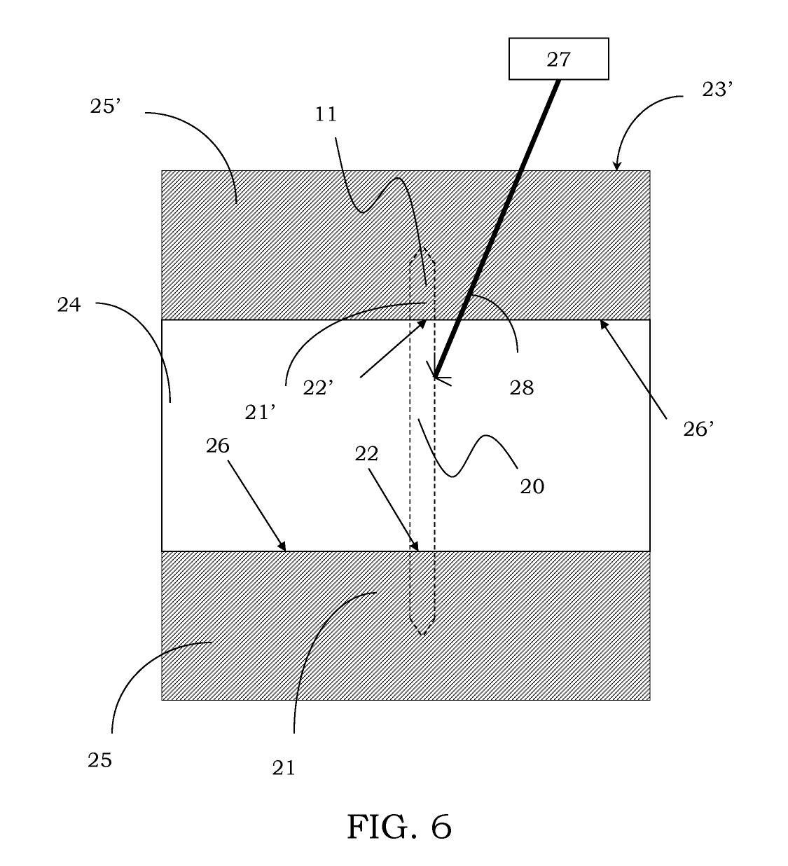

Moreover, in that case also, as shown in FIG. 6, the laser-cutting operation can be carried out for example by means of a dedicated laser equipment 27 able to direct a cutting laser beam 28 on the multi-material laminate 23.

It should be underlined that the actual cutting and separation of the contact probe 11 from the multi-material laminate 23 may include a plurality of passages of the cutting laser beam 28 in correspondence of the contour of the contact probe 11.

Furthermore, given the use of different materials in order to make the sheets of multi-material laminate 23, the number of passages of that cutting laser beam 28 may be different according to the considered material, particularly it will be grater for a material having greater hardness.

In one preferred embodiment, the manufacturing method includes a number of passages of the cutting laser beam 28 calibrated in order to separate the material of greater hardness used in the multi-material laminate 23.

In conclusion, advantageously according to an embodiment of the disclosure, a contact probe having a high conductivity section is obtained, being able to increase the current densities the probe can withstand to and to improve the heat dissipation, being soldered to a higher hardness section which is arranged in correspondence of the contact pads of the device under test and being able to improve the sliding of the contact tip thereon and extending the probe useful life, as well as at the probe portion sliding in the guiding holes, avoiding scratches on the probe or the probe itself getting stuck.

Furthermore, the contact probe may include an outer coating layer having even higher hardness, being able to generally improve the mechanical performance of the probe.

Moreover, by virtue of the improved contact probe performances, such as the improved current capability by virtue of the high conductivity layer and the hardness of the outer coating layer, it is possible to reduce the cross-section and consequently also the length of the probe, for example up to halving it compared to known probes being used for similar applications. It is immediately clear how the probe length reduction, the performances being equal, allows reducing the RLC parasitic effects and particularly the inductance value, with an advantage on the performance of the contact probe as a whole, particularly over frequency.

Finally, conveniently, the probes according to an embodiment of the disclosure can be made by means of laser-cutting a multi-material laminate being obtained soldering sheets of different materials and using a cutting laser beam for a number of passages being calibrated on the basis of the material to be cut and particularly of the material having the highest hardness among those forming the multi-material laminate.

From the foregoing it will be appreciated that, although specific embodiments of the disclosure have been described herein for purposes of illustration, various modifications may be made without deviating from the spirit and scope of the disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A contact probe for a testing head of an apparatus for testing electronic devices comprises:
a body extending between a contact tip and a contact head, and
at least one first section and one second section made of two respective different materials and soldered together at a soldering line,
the contact head being included only in the first section and the contact being included only in the second section.

2. The contact probe of claim 1, wherein the first section is made of a first conductive material and in that the second section is made of a second conductive material, the second conductive material having hardness values greater than those of the first conductive material.

3. The contact probe of claim 2, wherein the first conductive material is a metal or a metal alloy selected from copper, silver, gold or their alloys.

4. The contact probe of claim 2, wherein the second conductive material has hardness values greater than 250 Hv in Vickers Scale (equivalent to 2451.75 MPa).

5. The contact probe of claim 2, wherein the second conductive material is a metal or a metal alloy selected from nickel or an alloy thereof, tungsten or an alloy thereof, or a multilayer containing tungsten, or palladium or an alloy thereof, or rhodium or an alloy thereof.

6. The contact probe of claim 1 comprising a further section joined to the first section in correspondence of a further soldering line, the further section including the contact head of the contact probe and the first section being centrally arranged with respect to a longitudinal axis of said contact probe, the second section and further section being arranged on opposite sides with respect to the first section at the end portions of the contact probe.

7. The contact probe of claim 6, wherein the further section is made of the second conductive material making the second section.

8. The contact probe of claim 6, wherein the further section is made of a further conductive material different from the second conductive material making the second section, the further conductive material having hardness values greater than those of the first conductive material.

9. The contact probe of claim 8, wherein the further conductive material is a metal or a metal alloy selected from nickel or an alloy thereof, tungsten or an alloy thereof, or a multilayer containing tungsten, or palladium or an alloy thereof, or rhodium or an alloy thereof.

10. The contact probe of claim 1, further comprising an outer coating layer made of a third conductive material having hardness values greater than those of the first and second conductive materials.

11. The contact probe of claim 10, wherein the outer coating layer is a metal or a metal alloy, in particular rhodium, platinum, or a metal alloy thereof or palladium or an alloy thereof.

12. A testing head of an apparatus for testing electronic devices, comprising a plurality of contact probes, each contact probe comprising:
a body extending between a contact tip and a contact head, and
at least one first section and one second section made of two respective different materials and soldered together at a soldering line,
the contact head being included only in the first section and the contact being included only in the second section.

13. The testing head of claim 12, wherein the first section is made of a first conductive material and the second section is made of a second conductive material, the second conductive material having hardness values greater than those of the first conductive material.

14. The testing head of claim 13, wherein the first conductive material is a metal or a metal alloy selected from copper, silver, gold or their alloys and the second conductive material is a metal or a metal alloy selected from nickel or an alloy thereof, or tungsten or an alloy thereof, or a multilayer containing tungsten, or palladium or an alloy thereof, or rhodium or an alloy thereof.

15. The testing head of claim 12, wherein each contact probe further comprises an outer coating layer made of a third conductive material having hardness values greater than those of the first and second conductive materials.

16. The testing head of claim 15, wherein the outer coating layer is a metal or a metal alloy, in particular rhodium, platinum, or a metal alloy thereof or palladium or an alloy thereof, or even a nickel-phosphorus alloy.

17. A method for manufacturing a contact probe including a body extending between a contact tip and a contact head, and at least one first section and one second section made of two respective different materials and soldered together at a soldering line, the method comprising the following steps:
preparing a multi-material sheet being obtained by soldering a first sheet made of a first conductive material to a second sheet made of a second material in correspondence of a soldering string; and
realizing a contact probe of the multi-material sheet in order to define the first section of the contact probe in the first sheet and the second section in the second sheet, joined in correspondence of a soldering line which is a portion of the soldering string, the first section including the contact head of the contact probe and the second section including the contact tip of the contact probe.

18. The manufacturing method of claim 17, wherein the step of preparing the multi-material sheet comprises soldering a further sheet made of a further material to the first sheet in correspondence of a further soldering string and wherein the step of realizing also includes a definition of a further section in the further sheet, the first section and the further section being joined in correspondence of a further soldering line which is a portion of the further soldering string.

19. The manufacturing method of claim 17, wherein the step of realizing the contact probe in the multi-material sheet comprises a masking process and a following chemical etching, with one or more masking and etching steps.

20. The manufacturing method of claim 17, wherein the step of realizing the contact probe in the multi-material sheet comprises a laser-cutting step.

21. The manufacturing method of claim 20, wherein the laser-cutting step includes a plurality of passages of a cutting laser beam in correspondence of a contour of the contact probe.

22. The manufacturing method of claim 21, wherein the laser-cutting step includes a number of passages of the cutting laser beam calibrated in order to separate the material of greater hardness used in the multi-material sheet.
